(19) United States
(12) Patent Application Publication
(10) Pub. No.: US 2024/0153959 A1
(43) Pub. Date: May 9, 2024

(54) ARRAY SUBSTRATE AND MANUFACTURING METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Chuanbao Luo, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 17/755,871

(22) PCT Filed: Apr. 24, 2022
(86) PCT No.: PCT/CN2022/088653

§ 371 Date: Oct. 19, 2023

(30) Foreign Application Priority Data
Apr. 14, 2022 (CN) 20210393973.0

(51) Int. Cl. H01L 27/12; H01L 25/16

(52) U.S. Cl. CPC H01L 27/1222; H01L 27/1259; H01L 25/167; H01L 27/1248

(57) ABSTRACT

An array substrate, a manufacturing method thereof, and a display panel are provided. The array substrate includes a stacked substrate, a first active layer, a first gate electrode, a second active layer, and a second gate electrode. The active layer includes a first channel portion opposite to the first gate electrode, the second active layer includes a second channel portion opposite to the second gate electrode. The first active layer and the second active layer are connected in parallel, and the first channel portion and the second channel portion are separately provided.

### FIELD OF INVENTION

The present application relates to the field of display technology, and in particular, to an array substrate, a manufacturing method thereof, and a display panel.

### BACKGROUND OF INVENTION

The materials of the active layer in common thin film transistors generally include an amorphous silicon, a low temperature polysilicon and oxide. Oxide TFTs are widely used in TFT devices in the display industry due to their low leakage current and high mobility.

For the currently oxide TFTs with top gate electrode structure, because an upper limitation of a mobility of this type of device is lower, a double gate structure or a double active layer structure is usually used to improve the mobility of the oxide TFTs. However, the mobility improvement of the double-gate structure for oxide TFT is usually only 1.4 times a mobility of the single gate electrode structure, while the thickness of each active layer in the dual active layer structure is difficult to control, and the device uniformity is poor, which causes the oxide TFTs cannot meet the requirements of high-resolution products.

### SUMMARY OF INVENTION

The present application provides an array substrate, a manufacturing method thereof, and a display panel to provide an array substrate with good device uniformity and high mobility.

The present application provides an array substrate, which includes:
a substrate;
a first active layer disposed on the substrate, wherein the first active layer comprises a first channel portion;
a first gate electrode disposed on the first active layer, wherein the first gate electrode is disposed opposite to the first channel portion;
a second active layer disposed on the first gate electrode, wherein the second active layer comprises a second channel portion; and
a second gate electrode disposed on the second active layer, wherein the second gate electrode is disposed opposite to the second channel portion;
wherein the first active layer and the second active layer are connected in parallel, and wherein the first channel portion and the second channel portion are provided separately.

The present application provides a method of manufacturing an array substrate, which includes:
providing a substrate;
forming a first active layer on the substrate;
forming a first gate electrode on the first active layer, wherein the first gate electrode is disposed opposite to a first channel portion of the first active layer;
forming a second active layer on the first gate electrode, wherein the first active layer and the second active layer are connected in parallel, and wherein the first channel portion and a second channel portion of the second active layer are provided separately; and
forming a second gate electrode on the second active layer, and wherein the second gate electrode is disposed oppositely to the second channel portion.

The present application also provides a display panel, wherein the display panel includes an array substrate and a light-emitting member positioned on one side of the array substrate, and wherein the array substrate and the light-emitting member are combined into one body, and the array substrate includes:
a substrate;
a first active layer disposed on the substrate, wherein the first active layer comprises a first channel portion;
a first gate electrode disposed on the first active layer, wherein the first gate electrode is disposed opposite to the first channel portion;
a second active layer disposed on the first gate electrode, wherein the second active layer comprises a second channel portion; and
a second gate electrode disposed on the second active layer, wherein the second gate electrode is disposed opposite to the second channel portion;
wherein the first active layer and the second active layer are connected in parallel, and wherein the first channel portion and the second channel portion are provided separately.

In the present application, the double-layer active layers connected in parallel are disposed on the substrate, the double-layer gate electrode structure is conducted by the double-layer active layers, wherein the first active layer and the second active layer are in common conduction. A conduction channel of the device is increased by the common conduction of the first active layer and the second active layer, and a film thickness of each active layer can be precisely regulated by the two separated active layers, thereby improving a uniformity of the device while ensuring an electron mobility of the device.

### DESCRIPTION OF FIGURES

FIG. 1 is a first structural diagram of an array substrate of the present application.

FIG. 2 is a second structural diagram of the array substrate of the present application.

FIG. 3 is a third structural diagram of the array substrate of the present application.

FIG. 4 is a step diagram of a manufacturing method of the array substrate of the present application.

FIG. 5A to FIG. 5H are diagrams showing steps of the manufacturing process of the array substrate of the present application.

### DETAILED DESCRIPTION OF EMBODIMENTS

In order to make the objectives, technical solutions and effects of the present application clearer, the present application will be further described in detail below with reference to the accompanying figures and embodiments. It should be understood that the specific embodiments described herein are only used to explain the present application, but not to limit the present application.

The currently array substrate usually adopts a double gate structure or a double active layer structure to improve the mobility of the oxide TFT. However, the double active layers are stacked, causes the thicknesses of each of the active layer are difficult to control, and causes the uniformity of the device is poor. Therefore, the present application provides an array substrate to solve the above technical problems.

The present application provides an array substrate 100, which includes a substrate 110, a first active layer 140 disposed on the substrate 110, a first gate electrode 160 disposed on the first active layer 140, a second active layer 180 disposed on the electrode 160, and a second gate electrode 210 disposed on the second active layer 180.

In one embodiment, the first active layer 140 includes a first channel portion 141, the second active layer 180 includes a second channel portion 181, the first gate electrode 160 is disposed opposite to the first channel portion 141, and the second gate electrode 210 is disposed opposite to the second channel portion 181.

In one embodiment, the first active layer 140 and the second active layer 180 are connected in parallel, and the first channel portion 141 and the second channel portion 181 are provided separately.

In one embodiment, the present application provides two layers of active layers connected in parallel on the substrate 110, and uses a two-layer gate electrode structure to conduct conduction on the two layers of active layers, the common conduction of the first active layer 140 and the second active layer 180, and a film thickness of each active layer can be precisely regulated by the two separated active layers, thereby improving an uniformity of the device while ensuring an electron mobility of the device.

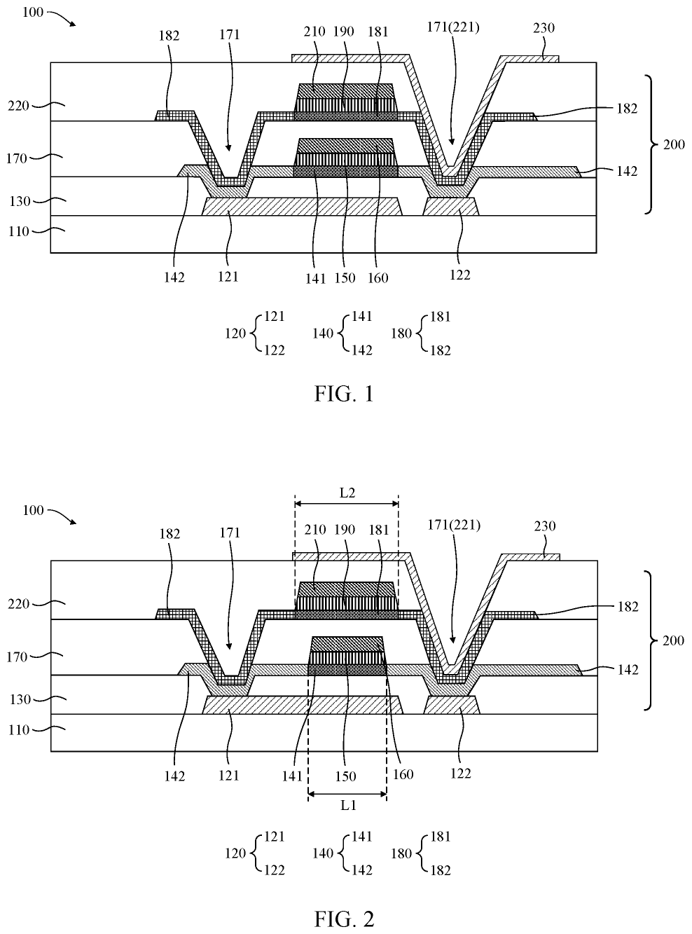

Referring to FIG. 1, the array substrate 100 includes a substrate 110 and a driving circuit layer 200 disposed on the substrate 110. The driving circuit layer 200 includes a thin film transistor, wherein the thin film transistor may be an etch stop type transistor, a back etching channel type transistor, or a bottom-gate thin film transistor and a top-gate thin film transistor which are determined according to the positions of the gate electrode and the active layer.

In one embodiment, the material of the substrate 110 may be a glass, a quartz, or a polyimide.

In one embodiment, please refer to FIG. 1, the array substrate 100 includes:

A first active layer 140 is disposed on the substrate 110, wherein the first active layer 140 includes a first channel portion 141 and first conductor portions 142 on both sides of the first channel portion 141. A material of the first active layer 140 may be metal oxides, such as IGZO, IGTO, Ln-IZO, ITZO, ITGZO, HIZO, IZO(InZnO), ZnO:F, In2O3:Sn, In2O3:Mo, Cd2SnO4, ZnO:Al, TiO2:Nb, Cd—Sn—O or other metal oxides, the following embodiments of the present application take IGZO as an example for description.

A first gate insulating layer 150 is disposed on the first active layer 140, and the first gate insulating layer 150 is used to isolate an upper metal layer from the first active layer 140. In one embodiment, a material of the first gate insulating layer 150 includes compounds composed of nitrogen, silicon and oxygen.

A first gate electrode 160 is disposed on the first gate insulating layer 150, and a material of the first gate electrode 160 includes metals or alloys such as Cr, W, Ti, Ta, Mo, Al, and Cu. The patterns of the first gate electrode 160 and the first gate insulating layer 150 are the same. The first gate 160 opposites to the first channel portion 141, that is, an orthographic projection of the first channel portion 141 on the first gate electrode 160 is positioned at inside the first gate electrode 160 to protect the first channel portion 141 from being affected by external light.

An interlayer insulating layer 170 is disposed on the first gate electrode 160, wherein the interlayer insulating layer 170 is laid over an entire layer and covers the first gate electrode 160 and the first active layer 140. A material of the interlayer insulating layer 170 in this embodiment can be composed of compounds composed of nitrogen elements, silicon elements and oxygen elements, such as a single-layer silicon oxide film layer, or a stacked structure of silicon oxide-silicon nitride-silicon oxide. In one embodiment, the interlayer insulating layer 170 is provided with a plurality of first through holes 171, and each of the first through hole 171 exposes part of the first conductor portion 142.

A second active layer 180 is disposed on the interlayer insulating layer 170. The second active layer 180 includes a second channel portion 181 and second conductor portions 182 positioned on both sides of the second channel portion 181. The first conductor portions 142 are electrically connected to the opposite second conductor portions 182 through the first through holes 171. In one embodiment, a material of the second active layer 180 is the same as the material of the first active layer 140.

A second gate insulating layer 190 is disposed on the second active layer 180, and the second gate insulating layer 190 is configured to isolate an upper metal from the second active layer 180. In one embodiment, a material of the second gate insulating layer 190 includes compounds composed of nitrogen, silicon and oxygen.

A second gate electrode 210 is disposed on the second gate insulating layer 190, and a material of the second gate electrode 210 is the same as a material of the first gate electrode 160. The patterns of the second gate electrode 210 and the second gate insulating layer 190 are the same, and the second gate electrode 210 opposites to the second channel portion 181. That is, an orthographic projection of the second channel portion 181 on the second gate electrode 210 is positioned inside the second gate electrode 210 to protect the second channel portion 181 from being affected by external light.

A passivation layer 220 is disposed on the second gate electrode 210, and the passivation layer 220 is laid over a whole layer and covers the second gate electrode 210 and the second active layer 180. In one embodiment, a material of the passivation layer 220 can be composed of a compound including nitrogen, silicon, and oxygen, such as a single-layer silicon oxide film layer, or a silicon oxide-silicon nitride stack structure. In one embodiment, a plurality of second through holes 221 are disposed on the passivation layer, and wherein each of the second through holes 221 expose part of the second conductor portion 182.

The pixel electrode layer 230 is disposed on the passivation layer 220, and the pixel electrode layer 230 is electrically connected to the second conductor portion 182 by the second through hole 221. A material of the pixel electrode layer 230 is a transparent metal material such as indium tin oxide.

In one embodiment, referring to FIG. 1, the array substrate 100 may further include a source-drain layer 120 disposed between the substrate 110 and the first active layer 140, and a buffer layer 130 disposed between the source-drain layer 120 and the first active layer 140.

In one embodiment, the source-drain layer 120 includes a source electrode 121 and a drain electrode 122 which are separately disposed, wherein the source electrode 121 and the drain electrode 122 are respectively electrically connected to the first conductor portions 142 on both sides of the first active layer 140.

In one embodiment, a material of the source-drain layer 120 may include alloys or metals such as Cr, W, Ti, Ta, Mo, Al, and Cu.

In one embodiment, a material of the buffer layer 130 may include a compound composed of nitrogen, silicon, and oxygen, such as a single-layer silicon oxide film layer or a silicon oxide-silicon nitride stack structure.

In the array substrate 100 of the present application, please refer to FIG. 1, in a top view direction of the array substrate 100, an orthographic projection of the first channel portion 141 on the source electrode 121 is positioned in the source electrode 121.

In the currently array substrate 100, a mobility of the active layer will be affected when the channel of the thin film transistor is exposed to light, thereby causing a certain drift in performance of the thin film transistor. In one embodiment, the first active layer 140 is disposed close to the substrate 110. If the array substrate 100 of the present application is applied to a liquid crystal display panel, the backlight light of back light source will enter the thin film transistor through the substrate 110, resulting in the mobility of the active layer. affected.

In one embodiment, the source electrode 121 can continue to extend toward the drain electrode 122, and an orthographic projection of the first channel portion 141 on the source electrode 121 is positioned in the source electrode 121. The source electrode 121 in one embodiment can also be used as a light shielding layer in addition to serving as a signal input terminal. In the present application, by extending the source electrode 121 toward the drain electrode 122 and blocking the first channel portion 141, the first channel portion 141 is protected from external light.

In one embodiment, the source electrode 121 and the drain electrode 122 are interchangeable, so in this embodiment, an orthographic projection of the first channel portion 141 on the drain electrode 122 can also be positioned in the drain electrode 122.

In one embodiment, since the first gate electrode 160 is disposed between the first active layer 140 and the second active layer 180, a voltage of the first gate electrode 160 can make the first active layer 140 turn on and can also act on the second active layer 180, and since the second gate electrode 210 is disposed on a side of the second active layer 180 away from the first active layer 140, the second gate electrode 210 can only act on the second active layer 140. As a result, the first active layer 140 is turned on by the voltage of the first gate electrode 160, and the second active layer 180 is turned on by the voltage of the first gate electrode 160 and the second gate electrode 210, resulting there is a difference in the turn-on speed of the first active layer 140 and the second active layer 180. Therefore, a turn-on rate of the channel portion in the first active layer 140 may be less than a turn-on rate of the channel portion in the second active layer 180, resulting in a delay in data transmission.

In one embodiment, please refer to FIG. 2, a length L1 of the first channel portion 141 is less than a length L2 of the second channel portion 181. Since the first channel portion 141 is only driven by the first gate electrode 160, and the second channel portion 181 is driven by the first gate electrode 160 and the second gate electrode 210 at the same time. In this embodiment, the length L1 of the first channel portion 141 is reduced, which is also in fact to reduce a distance between the two first conductor portions 142, thereby increasing a conduction rate of the two first conductor portions 142. That is, a difference between the first channel portion 141 and the second channel portion 181 being driven by different numbers of gates is balanced, the technical problem of the difference in the turn-on rates of the first active layer 140 and the second active layer 180 is solved, and ensuring a consistency of transmission rates of data signals from different active layers.

In the array substrate 100 of the present application, a mass ratio of oxygen elements in the first channel portion 141 is less than a mass ratio of oxygen elements in the second channel portion 181. An electron mobility of the channel portion, in addition to being affected by the external electric field, may also be related to material properties. For example, a material in the channel portion is generally IGZO. In one embodiment, by reducing the mass ratio of oxygen in the first channel portion 141, that is, reducing the mass ratio of oxygen in the metal oxide in the first channel portion 141, a mass ratio of metal is increased thereby improving an electron mobility of the first channel portion 141, balancing the difference between the first channel portion 141 and the second channel portion 181 being driven by different numbers of gates, the technical problem of the difference in the turn-on rate of the first active layer 140 and the second active layer 180 is solved, and the consistency of the transmission rate of data signals from different active layers is ensured.

In one embodiment, in addition to the first gate electrode 160 serving as a switch for turning on the first active layer 140, and the second gate electrode 210 serving as a switch for turning on the second active layer 180, the first gate electrode 160 is also be configured to as a light shielding member of the first channel portion 141, the second gate electrode 210 is also be configured to as a light shielding member of the second channel portion 181. Due to external light may also enter the panel through one side of the pixel electrode layer 230 of the array substrate 100, and then illuminate the first channel portion 141 and the second channel portion 181, therefore, in order to prevent external light from irradiating the corresponding channel portion, an area of the first gate electrode 160 and an area of the second gate electrode 210 are disposed larger than area of the opposite channel portions.

In the currently display panels, the oxides of narrow-bandgap elements combined with oxygen belong to the narrow-bandgap oxides, wherein the narrow-bandgap oxides have poor stability. This leads to a drift in a performance of thin film transistors.

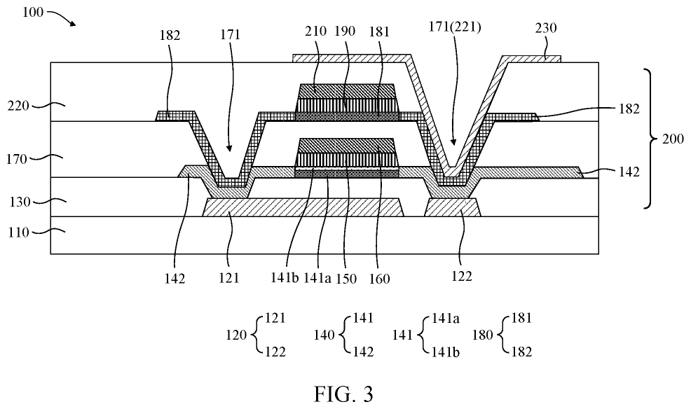

In the array substrate 100 of the present application, please refer to FIG. 3, the first channel portion 141 includes a first sub-channel 141a on a side of the first channel portion 141 close to the substrate 110 and a second sub-channel 141b on a side of the first channel portion 141 away from the substrate 110. A mass ratio of the narrow bandgap elements in the first sub-channel 141a is greater than a mass ratio of the narrow bandgap elements in the second sub-channel 141b.

In one embodiment, due to the oxide doped in the channel portion is composed of narrow bandgap elements and wide bandgap elements, and the second sub-channel 141b is disposed close to the light-emitting side, and the first sub-channel 141a is positioned between the substrate 110 and the second sub-channel 141b, only the second sub-channel 141b is illuminated when the external light enters the display panel. Since the mass ratio of the narrow bandgap elements in the second sub-channel 141b is less than the mass ratio of the wide bandgap elements, and wherein the oxide in the second sub-channel 141b are mainly composed of wide bandgap metal oxides, therefore, under long-term illumination conditions, an influence of illumination on the second sub-channels 141b is less than an influence of illumination on the first sub-channels 141a, while the first sub-channels 141a are covered by the second sub-channels 141b, so the first sub-channel 141a is less affected by illumination than the second sub-channels 141b, that is, a stability of the thin film transistor device is ensured.

In one embodiment, taking IGZO as an example, indium is a narrow bandgap element, and gallium and zinc are wide bandgap elements. Therefore, the present application needs to reduce a mass ratio of indium element in the second sub-channel 141b.

In one embodiment, although the first gate electrode 160 shields the first channel portion 141, there is still a certain amount of light leakage into the first channel portion 141 in edge regions of the first channel portion 141. The second channel portion 181 can be disposed in a same manner as the first channel portion 141, therefore it is necessary to balance the electron mobilities of the first channel portion 141 and the second channel portion 181.

In one embodiment, in addition to a stability factor, because the first channel portion 141 and the second channel portion 181 are driven by different numbers of gate electrodes, the present application reduces a proportion of narrow bandgap elements in the narrow-bandgap oxide in the first channel portion 141 to improve an optical and a thermal stability of the first channel portion 141, thereby ensuring an improvement of the electron mobility of the first active layer 140, and solving the problem of difference in the turn-on rates of the first active layer 140 and the second active layer 180.

In the array substrate 100 of the present application, the mass ratio of the narrow bandgap elements in the first channel portion 141 gradually decreases in the direction from the substrate 110 to the first active layer 140.

In one embodiment, a light intensity received by the first channel portion 141 that is closer to the light-emitting side of the array substrate 100 is greater, and a light intensity received by the first channel portion 141 that is farther from the light emitting side of the array substrate 100 is weaker when the external light irradiates the first channel portion 141. Therefore, according to that different position of the first channel portion 141 receive different light intensities, the mass ratio of the narrow bandgap elements in the first channel portion 141 is set in a gradient according to positions, wherein the closer to the light-emitting side of the array substrate 100, the smaller the mass ratio of the narrow bandgap elements in the first channel portion 141, which improves the stability of the thin film transistor under illumination conditions.

In one embodiment, the second channel portion 181 can be set in the same manner as the first channel portion 141, and it is only necessary to balance the electron mobilities of the first channel portion 141 and the second channel portion 181.

In one embodiment, a surface of the second sub-channel 141b is treated with an acid solution containing fluorine ions on to balance the difference in the proportion of narrow-bandgap elements in the first sub-channel 141a and the second sub-channel 141b, to make the indium element is precipitated from the channel portion.

In one embodiment, a surface of the second sub-channel portion 141b is partially etched since an acid solution containing fluorine ions has a certain etching effect on the metal oxide in the channel portion after the precipitation of indium element.

The present application also provides a display panel, the display panel includes the above-mentioned array substrate 100 and a light-emitting member positioned on one side of the array substrate 100, wherein the array substrate 100 and the light-emitting member are combined into one body.

For example, the light-emitting component may be a backlight module when the display panel is a liquid crystal display panel, and the light-emitting component may be an organic light-emitting device or a Micro-LED when the display panel is a self-luminous display panel, which is not specifically limited in the present application.

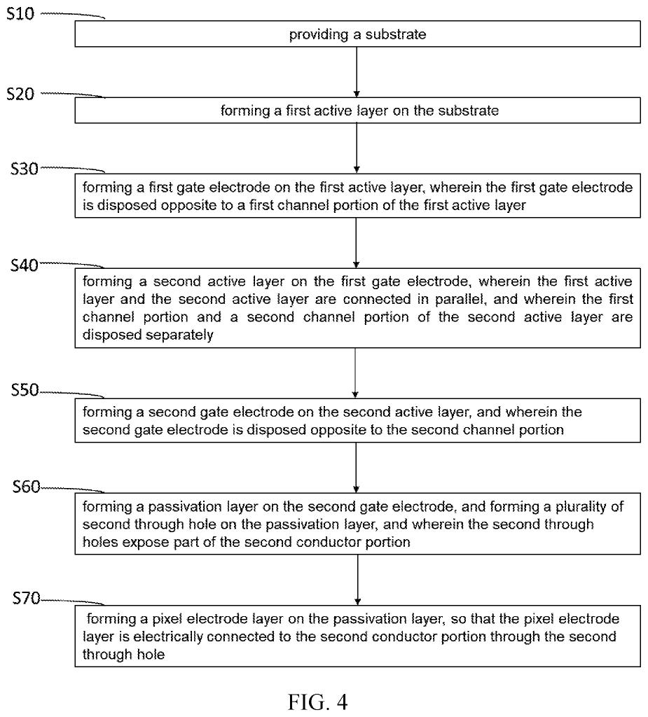

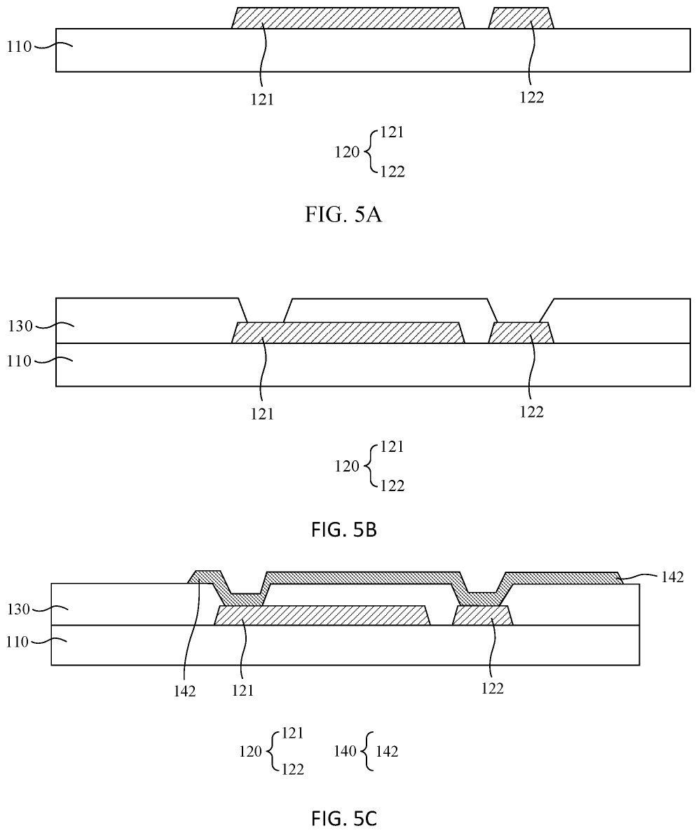

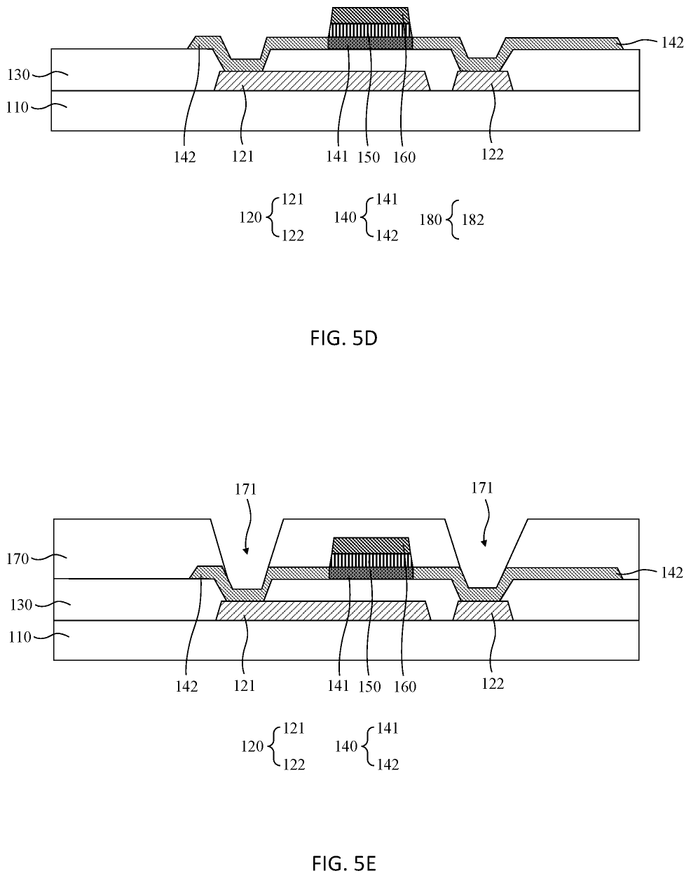

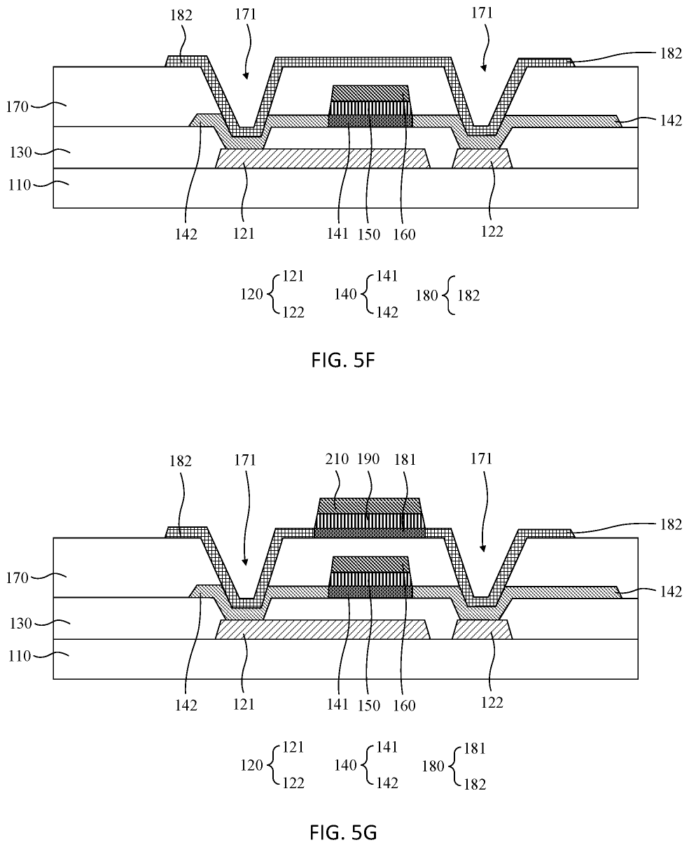

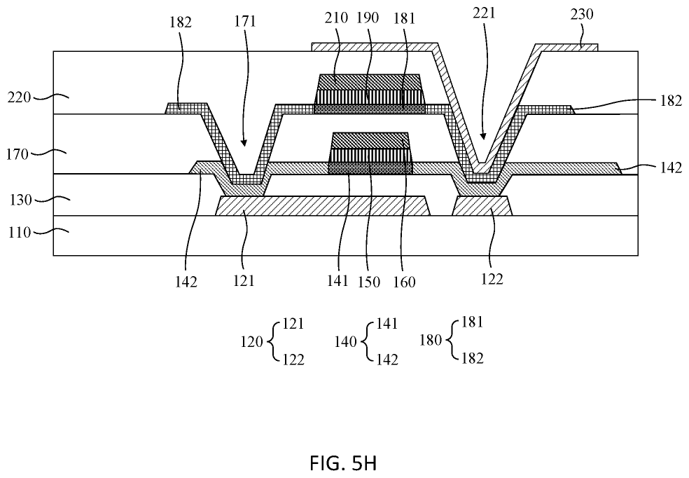

The present application provides a method of manufacturing an array substrate 100, please refer to FIG. 4, which includes:
S10, providing a substrate 110;
referring to FIG. 5A, a material of the substrate 110 may be glass, quartz, or polyimide.
S20, forming a first active layer 140 on the substrate 110;

In one embodiment, before step S20, method of manufacturing the array substrate 100 also includes:
forming a source and drain layer 120 on the substrate 110; and
forming a buffer layer 130 on the source-drain layer 120.

In one embodiment, please refer to FIG. 5A, the source and drain layer 120 includes a source electrode 121 and a drain electrode 122 arranged separately, and the source electrode 121 and the drain electrode 122 are respectively electrically connected to the first conductor portions 142 on both sides of the first active layer 140.

In one embodiment, a material of the source-drain layer 120 may include alloys or metals such as Cr, W, Ti, Ta, Mo, Al, and Cu.

In a conventional structure, the source and drain layer 120 is generally disposed above the active layer, wherein a lower active layer and an upper pixel electrode layer 230 are electrically connected. However, in the present application, due to the double active layer and double gate electrode, arranging the source-drain layer 120 above the active layer will further increase a complexity of a topography of surface the thin film transistor. In one embodiment, the source and drain layer 120 is disposed between the substrate 110 and the first active layer 140, since the surface of the substrate 110 is flat, a flatness of surface of the thin film transistor is improved, and a risk of disconnection of the source electrode 121 and drain electrode 122 is avoided.

In one embodiment, please refer to FIG. 5B, a material of the buffer layer 130 may include a compound composed of nitrogen, silicon and oxygen, such as a single-layer silicon oxide film, or a silicon oxide-silicon nitride stack structure.

In step S20, referring to FIG. 5C, a material of the first active layer 140 may be metal oxides, such as IGZO, IGTO, Ln-IZO, ITZO, ITGZO, HIZO, IZO(InZnO), ZnO:F, In2O3:Sn, In2O3:Mo, Cd2SnO4, ZnO:Al, TiO2:Nb, Cd—Sn—O or other metal oxides, the following embodiments of the present application take IGZO as an example for description.

In step S20, both ends of the first active layer 140 are electrically connected to the opposite source electrode 121 and the drain electrode 122 by through holes on the buffer layer 130.
S30, forming a first gate electrode 160 on the first active layer 140, wherein the first gate electrode 160 is disposed opposite to a first channel portion 141 of the first active layer 140.

In one embodiment, referring to FIG. 5D, step S30 may include:
forming a first gate insulating material layer and a first gate material layer on the first active layer 140;
patterning the first gate insulating material layer and the first gate material layer to form a first gate electrode 160 and a first gate insulating layer 150 opposite to the first channel portion 141;
treating the first active layer 140 with plasma to form the first conductor portions 142 in the region not covered by the first gate electrode 160 and the first gate insulating layer 150, wherein a structure between the first conductor portions 142 is the first channel portion 141;
forming an interlayer insulating layer 170 on the first gate electrode 160, wherein a plurality of first through holes 171 are formed on the interlayer insulating layer 170, and wherein each of the first through holes 171 expose part of the first conductor portion 142.

In one embodiment, the first gate material layer is firstly patterned when the first gate insulating material layer and the first gate material layer are patterned, so that the first gate material layer forms the first gate electrode 160, then patterning in a self-aligned manner with the first gate electrode 160, so that the first gate insulating material forms the first gate insulating layer 150.

In one embodiment, the first gate electrode 160 may be formed by, but not limited to, a wet etching process, and the first gate insulating layer 150 may be formed by, but not limited to, a dry etching process.

In one embodiment, the first gate insulating layer 150 is used to isolate an upper metal layer from the first active layer 140. In one embodiment, a material of the first gate insulating layer 150 may compose of compounds including nitrogen, silicon, and oxygen.

In one embodiment, a material of the first gate electrode 160 may include metals or alloys such as Cr, W, Ti, Ta, Mo, Al, and Cu. The patterns of the first gate electrode 160 and the first gate insulating layer 150 are the same. The first gate electrode 160 opposites to the first channel portion 141, that is, an orthographic projection of the first channel portion 141 on the first gate electrode 160 may be positioned at inside the first gate electrode 160 to protect the first channel portion 141 from being affected by external light.

In one embodiment, please refer to FIG. 5E, the interlayer insulating layer 170 is laid over an entire layer and covers the first gate electrode 160 and the first active layer 140. A material of the interlayer insulating layer 170 in this embodiment can be composed of compounds composed of nitrogen elements, silicon elements and oxygen elements, such as a single-layer silicon oxide film layer, or a stacked structure of silicon oxide-silicon nitride-silicon oxide.
S40, forming a second active layer 180 on the first gate electrode 160, wherein the first active layer 140 and the second active layer 180 are connected in parallel, and wherein the first channel portion 141 and a second channel portion 181 of the second active layer 180 are disposed separately;

In this step, please refer to FIG. 5F, the second active layer 180 is electrically connected to the first conductor portions 142 of the first active layer 140 through the first through hole 171, which is equivalent to the head and tail ends of the first active layer 140 and the second active layer 180 are connected to form a parallel structure.
S50, forming a second gate electrode 210 on the second active layer 180, and wherein the second gate electrode 210 is disposed opposite to the second channel portion 181.

In one embodiment, referring to FIG. 5G, step S50 includes:
forming a second gate insulating material layer and a second gate material layer on the second active layer 180;
patterning the second gate insulating material layer and the second gate material layer to form a second gate electrode 210 and a second gate insulating layer 190 opposite to the second channel portion 181; and
treating the second active layer 180 with plasma to form the second conductor portions 182 in the region not covered by the second gate electrode 210 and the first gate insulating layer 150, and wherein a structure between the second conductor portions 182 is the second channel portion 181.

In one embodiment, the second gate material layer is firstly patterned when patterning the second gate insulating material layer and the second gate material layer, so that the second gate material layer forms the second gate electrode 210, and then patterning in a self-aligned manner with the second gate electrode 210, so that the second gate insulating material forms the first gate insulating layer 190.

In one embodiment, the second gate electrode 210 may be formed by, but not limited to, a wet etching process, and the second gate insulating layer 190 may be formed by, but not limited to, a dry etching process. In one embodiment, the second gate insulating layer 190 is used to isolate the second gate electrode 210 from the second active layer 180. In one embodiment, a material of the second gate insulating layer 190 may include compounds of nitrogen element, silicon element, and oxygen element.

In one embodiment, a material of the second gate electrode 210 is the same as a material of the first gate electrode 160. The patterns of the second gate electrode 210 and the second gate insulating layer 190 are the same, and the second gate electrode 210 opposites to the second channel portion 181. That is, an orthographic projection of the second channel portion 181 on the second gate electrode 210 is positioned inside the second gate electrode 210 to protect the second channel portion 181 from being affected by external light.
S60, forming a passivation layer 220 on the second gate electrode 210, and forming a plurality of second through hole 221 on the passivation layer 220, and wherein each of the second through holes 221 expose part of the second conductor portion 182.

Referring to FIG. 5H, the passivation layer 220 is laid over a whole layer and covers the second gate electrode 210 and the second active layer 180. In one embodiment, a material of the passivation layer 220 can be composed of a compound including nitrogen, silicon, and oxygen, such as a single-layer silicon oxide film layer, or a silicon oxide-silicon nitride stack structure. In one embodiment, a plurality of second through holes 221 are disposed on the passivation layer, and wherein each of the second through holes 221 expose part of the second conductor portion 182.
S70, forming a pixel electrode layer 230 on the passivation layer 220, so that the pixel electrode layer 230 is electrically connected to the second conductor portion 182 through the second through hole 221.

In one embodiment, please refer to FIG. 5H, a material of the pixel electrode layer 230 is a transparent metal material such as indium tin oxide.

The present application also proposes a mobile terminal, which includes a terminal body and the above-mentioned display panel, wherein the terminal body and the display panel are combined into one body. The terminal body may be a device such as a circuit board bound to the display panel and a cover plate or the like covering the display panel. The mobile terminal may include electronic devices such as a mobile phone, a TV, and a notebook computer.

It can be understood that, for those of ordinary skill in the art, equivalent replacements or changes can be made according to the technical solutions of the present application and the inventive concept thereof, and all these changes or replacements should belong to a protection scope of the appended claims of the present application.

What is claimed is:

1. An array substrate, comprising:
a substrate;
a first active layer disposed on the substrate, wherein the first active layer comprises a first channel portion;
a first gate electrode disposed on the first active layer, wherein the first gate electrode is disposed opposite to the first channel portion;
a second active layer disposed on the first gate electrode, wherein the second active layer comprises a second channel portion; and
a second gate electrode disposed on the second active layer, wherein the second gate electrode is disposed opposite to the second channel portion;
wherein the first active layer and the second active layer are connected in parallel, and wherein the first channel portion and the second channel portion are provided separately.

2. The array substrate according to claim 1, wherein the first active layer further comprises first conductor portions positioned on both sides of the first channel portion, and wherein the second active layer further comprises second conductor portions positioned on both sides of the second channel portion;
wherein the first conductor portions and the second conductor portions are electrically connected.

3. The array substrate according to claim 2, wherein the array substrate further comprises:
an interlayer insulating layer disposed on the first active layer, wherein the interlayer insulating layer comprises a plurality of first through holes, and wherein each of the first through holes expose part of the first conductor portion;
wherein the second active layer is disposed on the interlayer insulating layer, the second conductor portion overlaps inner walls of the first through holes, and wherein the second conductor portions are connected to the first conductor portions through the first through holes.

4. The array substrate according to claim 3, wherein the array substrate further comprises:
a passivation layer disposed on the interlayer insulating layer and covering the second gate electrode, wherein the passivation layer comprises a plurality of second through holes, and wherein each of the second through holes expose part of the second conductor portion.

5. The array substrate according to claim 2, wherein the array substrate further comprises:
a source and drain layer disposed between the substrate and the first active layer, wherein the source and drain layer comprises a source electrode and a drain electrode which are separately disposed, and wherein the source electrode and the drain electrode are respectively electrically connected to the first conductor portion on both sides of the first active layer.

6. The array substrate according to claim 5, wherein an orthographic projection of the first channel portion on the source electrode is positioned in the source electrode in a plan view direction of the array substrate.

7. The array substrate according to claim 2, wherein a length of the first channel portion is less than a length of the second channel portion.

8. The array substrate according to claim 2, wherein a mass ratio of oxygen elements in the first channel portion is less than a mass ratio of oxygen elements in the second channel portion.

9. The array substrate according to claim 2, wherein the first channel portion comprises a first sub-channel on a side of the first channel portion close to the substrate and a second sub-channel on a side of first channel portion away from the substrate, and wherein a mass ratio of a narrow band gap elements in the first sub-channel is greater than a mass ratio of a narrow band gap elements in the second sub-channel.

10. The array substrate according to claim 9, wherein the mass ratio of the narrow bandgap elements in the first channel portion gradually decreases in a direction from the substrate to the first active layer.

11. A method of manufacturing an array substrate, comprising:
providing a substrate;
forming a first active layer on the substrate;
forming a first gate electrode on the first active layer, wherein the first gate electrode is disposed opposite to a first channel portion of the first active layer;
forming a second active layer on the first gate electrode, wherein the first active layer and the second active layer are connected in parallel, and wherein the first channel portion and a second channel portion of the second active layer are provided separately; and
forming a second gate electrode on the second active layer, and wherein the second gate electrode is disposed oppositely to the second channel portion.

12. A display panel, wherein the display panel comprises an array substrate and a light-emitting member positioned on one side of the array substrate, and wherein the array substrate and the light-emitting member are combined into one, and wherein the array substrate comprises:
a substrate;
a first active layer disposed on the substrate, wherein the first active layer comprises a first channel portion;
a first gate electrode disposed on the first active layer, wherein the first gate electrode is disposed opposite to the first channel portion;
a second active layer disposed on the first gate electrode, wherein the second active layer comprises a second channel portion; and
a second gate electrode disposed on the second active layer, wherein the second gate electrode is disposed opposite to the second channel portion;
wherein the first active layer and the second active layer are connected in parallel, and wherein the first channel portion and the second channel portion are provided separately.

13. The display panel according to claim 12, wherein the first active layer further comprises first conductor portions positioned on both sides of the first channel portion, and wherein the second active layer further comprises second conductor portions positioned on both sides of the second channel portion;
wherein the first conductor portions and the second conductor portions are electrically connected.

14. The display panel according to claim 13, wherein the array substrate further comprises:
an interlayer insulating layer disposed on the first active layer, wherein the interlayer insulating layer comprises a plurality of first through holes, and wherein each of the first through holes expose part of the first conductor portion;
wherein the second active layer is disposed on the interlayer insulating layer, the second conductor portion overlaps inner walls of the first through holes, and wherein the second conductor portions are connected to the first conductor portions through the first through holes; and
a passivation layer disposed on the interlayer insulating layer and covering the second gate electrode, wherein the passivation layer comprises a plurality of second through holes, and wherein each of the second through holes expose part of the second conductor portion.

15. The display panel according to claim 13, wherein the array substrate further comprises:
a source and drain layer disposed between the substrate and the first active layer, wherein the source and drain layer comprises a source electrode and a drain electrode which are separately disposed, and wherein the source electrode and the drain electrode are respectively electrically connected to the first conductor portion on both sides of the first active layer.

16. The display panel according to claim 15, wherein an orthographic projection of the first channel portion on the source electrode is positioned in the source electrode in a plan view direction of the array substrate.

17. The display panel according to claim 13, wherein a length of the first channel portion is less than a length of the second channel portion.

18. The display panel according to claim 13, wherein a mass ratio of oxygen elements in the first channel portion is less than a mass ratio of oxygen elements in the second channel portion.

19. The display panel according to claim 13, wherein the first channel portion comprises a first sub-channel on a side of the first channel portion close to the substrate and a second sub-channel on a side of the first channel portion away from the substrate, and wherein a mass ratio of a narrow band gap elements in the first sub-channel is greater than a mass ratio of a narrow band gap elements in the second sub-channel.

20. The display panel according to claim 19, wherein the mass ratio of the narrow bandgap elements in the first channel portion gradually decreases in a direction from the substrate to the first active layer.
